(19) United States
(12) Patent Application Publication
(10) Pub. No.: US 2015/0091417 A1
(43) Pub. Date: Apr. 2, 2015

(54) PIEZOELECTRIC CERAMICS, PIEZOELECTRIC CERAMIC COMPOSITIONS, AND PIEZOELECTRIC ELEMENTS

(71) Applicants: Tomoaki KARAKI, Imizu-shi (JP); Tsunehiro KATAYAMA, Yoro-gun (JP); HITACHI METALS, LTD., Tokyo (JP)

(72) Inventors: Tomoaki KARAKI, Imizu-shi (JP); Tsunehiro KATAYAMA, Yoro-gun (JP)

(73) Assignee: TOYAMA Prefecture, Toyama-shi (JP)

(21) Appl. No.: 14/496,101

(22) Filed: Sep. 25, 2014

(30) Foreign Application Priority Data
Sep. 30, 2013 (JP) 2013-204281

(51) Int. Cl. H01L 41/187; H01L 41/047

(52) U.S. Cl. CPC H01L 41/1878; H01L 41/047; H01L 41/1871
USPC 310/365; 252/62.9 PZ

(57) ABSTRACT

A piezoelectric ceramic contains as a main component an oxide which is represented by the general formula: sA1B1O₃-t(Bi.A2)TiO₃-(1-s-t)BaMO₃ (where A1 is at least one element selected from among alkali metals; B1 is at least one element selected from among transition metal elements and contains Nb; A2 is at least one element selected from among alkali metals; and M is at least one element selected from the 4A group and contains Zr). In the general formula, s and t satisfy 0.905≦s≦0.918, 0.005≦t≦0.02, and a piezoelectric constant d33₍₂₅₎ at 25° C. and a piezoelectric constant d33₍₂₀₀₎ at 200° C. satisfy the relationship (d33₍₂₅₎−d33₍₂₀₀₎/d33₍₂₅₎≦0.13.

### BACKGROUND

1. Technical Field

The present application relates to lead-free piezoelectric ceramics, piezoelectric ceramic compositions, and piezoelectric elements.

2. Description of the Related Art

Various materials have conventionally been developed as piezoelectric materials for use in piezoelectric devices, e.g., ceramics, single crystals, and thick films and thin films. Among others, piezoelectric ceramics composed of PbZrO₃—PbTiO₃(PZT), which is a lead-containing perovskite-type ferroelectric, exhibit excellent piezoelectric characteristics. Therefore, they have been widely used in fields such as electronics, mechatronics, and automobiles.

However, increased awareness of environmental conservation in the recent years has led to a tendency to abstain from using metals such as Pb, Hg, Cd, and Cr⁶⁺ in electronic/electrical appliances, and prohibitive orders (the RoHS directive) have been issued and enforced chiefly in Europe.

In view of the wide use of conventional piezoelectric ceramics that contain lead, it is important and urgently necessary to study lead-free piezoelectric materials which give consideration to the environment. Therefore, lead-free piezoelectric ceramics which can exhibit performances rivaling those of conventional PZT-based piezoelectric ceramics are drawing attention.

Perovskite-type compounds are generally expressed as ABO₃. Among others, as ceramics of lead-free compositions with relatively high piezoelectric characteristics, ceramics are being studied in the recent years which are perovskite-type compounds such that an alkali metal such as Na, Li, or K is used at the A site and Nb, Ta, or the like is used at the B site as main components.

For example, WO2008/143160 discloses a piezoelectric solid solution composition whose main component is a composition represented by the general formula {Mₓ(Na_{y}Li_{z}K_{1-y-z})₁₋ₓ}₁₋ₘ{(Ti₁₋ᵤ₋ᵥZrᵤHfᵥ)ₓ(Nb_{1-w}Ta_{w})₁₋ₓ}O₃ (in the formula, M represents a combination of at least one selected from the group consisting of (Bi_{0.5}K_{0.5}), (Bi_{0.5}Na_{0.5}), and (Bi_{0.5}Li_{0.5}) and at least one selected from the group consisting of Ba, Sr, Ca, and Mg; and x, y, z, u, v, w, and m in the formula are in the following respective ranges: 0.06<x≦0.3, 0≦y≦1, 0≦z≦0.3, 0≦y+z≦1, 0<u≦1, 0≦v≦0.75, 0≦w≦0.2, 0<u+v≦1, −0.06≦m≦0.06).

### SUMMARY

The piezoelectric constant d33 is one of the parameters representing the piezoelectric characteristics of a piezoelectric ceramic. The piezoelectric constant d33 indicates an amount of charge that occurs when pressure is applied to a given material, such charge occurring in the direction of pressure. A piezoelectric ceramic having a large piezoelectric constant d33 allows a high-precision piezoelectric element with a good sensitivity to be produced. The value of the piezoelectric constant d33 is usually measured at room temperature.

One non-limiting, and exemplary embodiment provides a lead-free piezoelectric ceramic having excellent temperature stability, a composition for piezoelectric ceramics, and a piezoelectric element which attain a large piezoelectric constant d33 across a broad temperature range.

A piezoelectric ceramic according to the present disclosure comprises as a main component an oxide which is represented by the general formula: sA1B1O₃-t(Bi.A2)TiO₃-(1-s-t)BaMO₃ (where A1 is at least one element selected from among alkali metals; B1 is at least one element selected from among transition metal elements and contains Nb; A2 is at least one element selected from among alkali metals; and M is at least one element selected from the 4A group and contains Zr), wherein, s and t in the general formula satisfy 0.905≦s≦0.918, 0.005≦t≦0.02; and a piezoelectric constant d33₍₂₅₎ at 25° C. and a piezoelectric constant d33₍₂₀₀₎ at 200° C. satisfy the following relationship:

$$\frac{d {33}_{( 25 )} - d {33}_{( 200 )}}{d {33}_{( 25 )}} \leq 0.13 .$$

The piezoelectric constant d33₍₂₅₎ may be 200 pC/N or more.

In the general formula, s and t may satisfy

0.910≦s<0.918

0.006≦t≦0.015; and

the piezoelectric constant d33₍₂₅₎ and the piezoelectric constant d33₍₂₀₀₎ may satisfy the following relationship:

$$\frac{d {33}_{( 25 )} - d {33}_{( 200 )}}{d {33}_{( 25 )}} \leq 0.10 .$$

A piezoelectric element according to the present invention comprises a piezoelectric layer composed of any of above the piezoelectric ceramics, and a pair of electrodes between which the piezoelectric layer is interposed.

A composition for a piezoelectric ceramic according to the present disclosure comprises as a main component a composition represented by the general formula: sA1B1O₃-t(Bi.A2)TiO₃-(1-s-t)BaMO₃ (where A1 is at least one element selected from among alkali metals; B1 is at least one element selected from among transition metal elements and contains Nb; A2 is at least one element selected from among alkali metals; M is at least one element selected from the 4A group and contains Zr; and 0.905≦s≦0.918, 0.005≦t≦0.02).

In the general formula, s and t may satisfy:

0.910≦s<0.918

0.006≦t≦0.015.

The general formula may be s(KₓNa_{y}Li_{z})NbO₃-t(Bi_{0.5}Na_{0.5})TiO₃-(1-s-t)BaZrO₃(x+y+z=1).

According to the present disclosure, a piezoelectric ceramic having excellent temperature stability which can maintain a large piezoelectric constant d33 from room temperature to about 200° C. is realized. As a result, a piezoelectric element is obtained which stably operates in a wide range of temperature environments.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1 is a composition diagram indicating a composition range of a piezoelectric ceramic according to the present disclosure, in which compositions of Examples and Comparative Examples are shown.

FIG. 2 is an X-ray diffraction pattern of a piezoelectric ceramic according to Example 1-3.

FIG. 3 is an X-ray diffraction pattern of a piezoelectric ceramic according to Example 1-6.

FIG. 4 is a phase diagram illustrating phase boundaries.

FIG. 5 is an X-ray diffraction pattern of a piezoelectric ceramic according to Comparative Example 1-1.

### DETAILED DESCRIPTION

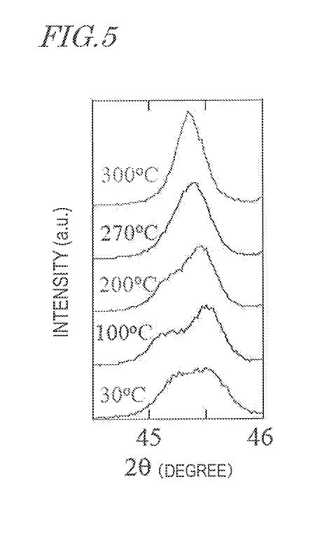

The inventors have conducted a detailed study on lead-free piezoelectric ceramics which can exhibit a performance rivaling those of conventional PZT-based piezoelectric ceramics. FIG. 4 schematically shows a relationship between the mole fractions and temperature and the crystal structure, with respect to oxides of the rhombohedral perovskite structure and oxides of the tetragonal perovskite structure. Generally, a solid solution of an oxide of the rhombohedral perovskite structure and an oxide of the tetragonal perovskite structure takes either one of the crystal phases depending on the mixing ratio at approximately 250° C. or lower. In this case, it is known that any crystal phase near the phase boundary can exhibit a high piezoelectric constant d33. The reason is that, a piezoelectric ceramic having a crystal structure near the phase boundary is likely to be strained upon deformation, thus having large displacement and generated charge. Generally speaking, a piezoelectric element is required to have a large piezoelectric constant d33 near room temperature, which is the temperature of the environment in which it will be used. Therefore, a composition which stays at the phase boundary at room temperature is to be used for a piezoelectric ceramic that is composed of a solid solution of an oxide of the rhombohedral perovskite structure and an oxide of the tetragonal perovskite structure.

In conventional lead-containing piezoelectric ceramics, as is indicated by a solid line in FIG. 4, the phase boundary between rhombohedral and tetragonal is substantially parallel to the temperature axis. A piezoelectric ceramic having such characteristics is always near the phase boundary irrespective of temperature, and therefore is able to stably maintain large displacement even if the temperature changes depending on the environment of use. In other words, their piezoelectric characteristics have excellent temperature stability.

However, in lead-free piezoelectric ceramics, as indicated by a broken line in FIG. 4, this phase boundary is oblique with respect to the temperature axis. In other words, conventional lead-free piezoelectric ceramics such as that of WO2008/143160 depart from the phase boundary as they shift from room temperature to higher temperatures, thus taking a completely tetragonal crystal structure, or undergoing a phase transition from rhombohedral to tetragonal or the like. Thus, their piezoelectric characteristics do not have sufficient temperature stability, and lead-free piezoelectric ceramics are not widely used as alternative materials to conventional lead-containing piezoelectric ceramics.

In view of such problems, the inventors have found that the temperature stability of piezoelectric characteristics can be enhanced by using ternary oxides. A piezoelectric ceramic according to the present disclosure contains as a main component an oxide which is represented by the general formula: sA1B1O₃-t(Bi.A2)TiO₃-(1-s-t)BaMO₃ (where A1 is at least one element selected from among alkali metals; B1 is at least one element selected from transition metal elements and contains Nb; A2 is at least one element selected from among alkali metals; and M is at least one element selected from the 4A group and contains Zr). In the general formula, s and t satisfy 0.905≦s≦0.918, 0.005≦t≦0.02. An oxide of this composition has a crystal structure near the phase boundary region between rhombohedral and tetragonal from room temperature to near Curie temperature, and does not exhibit any changes in crystal structure such as taking a completely rhombohedral or tetragonal crystal structure or undergoing a phase transition from rhombohedral to tetragonal, and so on. In other words, the crystal structure has high temperature stability. Specifically, among the three oxides in the above general formula, BaMO₃ and A1B1O₃ are respectively rhombohedral and tetragonal, and with the further inclusion of (Bi.A2)TiO₃, as indicated by the solid line in the state diagram of FIG. 4, the phase boundary between rhombohedral-tetragonal is substantially vertical, i.e., substantially parallel to the temperature axis, from room temperature to 200° C., albeit a lead-free composition. This piezoelectric ceramic is characterized by its piezoelectric constant d33 having little temperature change. Moreover, by baking the composition represented by the above general formula, a piezoelectric ceramic whose piezoelectric constant d33 has little temperature change is obtained. Therefore, even with a change in the temperature associated with the environment of use, its deforming nature is conserved because of the crystal structure near the phase boundary being maintained, whereby a substantially constant displacement of the piezoelectric ceramic can be kept.

Thus, a piezoelectric ceramic according to the present disclosure undergoes little change in the piezoelectric constant d33 from room temperature to 200° C. Specifically, a rate Δd33(=(d33₍₂₅₎−d33₍₂₀₀₎/d33₍₂₅₎) of the difference between the piezoelectric constant d33₍₂₅₎ at room temperature and the piezoelectric constant d33₍₂₀₀₎ at 200° C. to the piezoelectric constant d33₍₂₅₎ at room temperature (25° C.) is 0.13 or less. Thus, excellent temperature stability is obtained across a broad temperature range.

Thus, the present disclosure has been made based on an entirely novel concept in the realm of lead-free compositions, i.e., allowing the phase boundary to stand substantially vertically, and provides an excellent piezoelectric ceramic that is not conventionally available.

Hereinafter, the compositions of oxides which are the main component of the piezoelectric ceramic according to the present disclosure will be described in detail. The oxides are ternary system oxides of the compositions A1B1O₃, (Bi.A2)TiO₃, and BaMO₃.

[A1B1O₃]

In the present embodiment, the composition expressed as A1B1O₃ is a lead-free, alkali metal-containing niobium oxide. A1 is at least one element selected from among alkali metals, and B1 is at least one element selected from among transition metal elements and contains Nb.

This composition is known as the composition of a piezoelectric ceramic having a tetragonal perovskite structure with which a high piezoelectric constant is likely to be obtained, and exhibits high piezoelectric characteristics also in the present embodiment.

As Al, Na, K, Li, or the like can be used, for example, and it is particularly preferable to use all of Na, K, and Li. In other words, it is preferable that A1 is NaₓK_{y}Li_{z}(x+y+z=1). B1 always contains Nb. Specifically, it is preferable that 80 at % or more Nb is contained in all B1.

[BaMO₃]

BaMO₃ is a ceramic composition having a rhombohedral perovskite structure. M is at least one element selected from the 4A group and contains Zr. By mixing a composition expressed as BaMO₃ with a composition expressed as A1B1O₃, a piezoelectric ceramic having a tetragonal-rhombohedral phase boundary is obtained, which shows excellent piezoelectric characteristics. The composition expressed as BaMO₃ can also provide the effect of enhancing the dielectric constant.

[(Bi.A2)TiO₃]

(Bi.A2)TiO₃ is a ceramic composition having a rhombohedral perovskite structure.

In (Bi.A2)TiO₃, A2 is at least one element selected from among alkali metals, and specifically, includes at least one element selected from the group consisting of Li, Na, and K. A2 is preferably Na. Herein, (Bi.A2) means (Bi_{0.5}A2_{0.5}). However, A2 may vaporize during bake, and there may be a deviation in the composition after bake, within the significant digits of the ratio of (Bi_{0.5}A2_{0.5}), i.e., within the range of Bi:A2=0.45:0.54 to 0.54:0.45.

By using (Bi.A2)TiO₃ in addition to BaMO₃ as rhombohedral crystal, the temperature stability of the crystal structure is enhanced. As a result, a lead-free piezoelectric ceramic with good piezoelectric temperature characteristics is obtained.

In these three compositions, it is preferable that at least one of A1 and A2 contains Li. Moreover, it is preferable that Li exceeds 3.5 at % relative to the total amount of A1, Bi, A2, and Ba, and is contained at a rate of 8.0 at % or less. When Li is in this range, a high piezoelectric constant d33 can be obtained. Moreover, Li provides for sinterability and therefore is also effective in improving mechanical strength.

[Mole Fraction]

In the general formula: sA1B1O₃-t(Bi.A2)TiO₃-(1-s-t)BaMO₃, s and t satisfy 0.905≦s≦0.918, 0.005≦t≦0.02.

Outside this range, the phase boundary between tetragonal-rhombohedral becomes oblique, so that the rate Δd33(=(d33₍₂₅₎−d33₍₂₀₀₎/d33₍₂₅₎) of the difference between the piezoelectric constant d33₍₂₅₎ at room temperature and the piezoelectric constant d33₍₂₀₀₎ at 200° C. relative to the piezoelectric constant d33₍₂₅₎ at room temperature (25° C.) will exceed 0.13. Thus, a lead-free piezoelectric ceramic having excellent temperature stability cannot be obtained. It is more preferable that s and t satisfy the relationships of 0.910≦s≦0.918 and 0.006≦t≦0.015. As a result, a piezoelectric ceramic whose rate Δd33 of difference is 0.10 or less can be obtained.

In particular, t, which is the content rate of (Bi.A2)TiO₃, greatly affects the inclination of the phase boundary in FIG. 4. When t is less than 0.005, an inclination toward rhombohedral will occur, and when t exceeds 0.02, an inclination toward tetragonal will occur; in either case, it is difficult to obtain excellent temperature stability. Therefore, the neighborhood of t=0.01 is preferable, and it is more preferably not less than 0.006 and not more than 0.015.

(1-s-t), which represents the amount of BaMO₃, is preferably such that 0.07≦1-s-t≦0.085. When 1-s-t is in this range, a piezoelectric ceramic having a high piezoelectric constant d33 can be obtained. Furthermore, as described above, temperature stability of piezoelectric characteristics can be enhanced. It is more preferable that (1-s-t) satisfies the relationship 0.072<1-s-t≦0.080.

In the present disclosure, the term “main component” is applied when the composition of the above general formula is contained in an amount of 80 mol % or more. Other than the main component, the piezoelectric ceramic may contain various additives. For example, anything that allows the crystal structure of the perovskite-type compound to be maintained but does not deteriorate the characteristics of the piezoelectric constant d33 can be tolerated.

Hereinafter, a production method for piezoelectric ceramic according to the present disclosure will be described.

(1) Step of Source Material Preparation

In a step of preparing a source material, the aforementioned A1B1O₃, (Bi.A2)TiO₃, and BaMO₃ compositions may be weighed and mixed so as to respectively have the content rates indicated by the above general formula. Alternatively, elemental A1, B1, Bi, A2, Ti, Ba, and M, or oxides, carbonates, oxalates, hydrogencarbonates, hydroxides, etc., containing these elements may be weighed and mixed so that A1, B1, Bi, A2, Ti, Ba, and M, are contained at the mole fractions indicated by the general formula. Following a generic procedure of ceramic production via baking, the source material is mixed and pulverized by using a ball mill or the like.

(2) Calcination Step

In the aforementioned step of source material preparation, it is preferable that the prepared source material is calcined before molding. As for calcination conditions, it is preferably conducted in the air at a temperature of not less than 900° C. and not more than 1100° C. Preferably, the retention time is not less than 0.5 hours and not more than 10 hours.

(3) Molding Step

Next, the calcined powder which was obtained in the above manner is pulverized in a ball mill; a binder is added thereto; and it is molded into the shape of a piezoelectric ceramic. For the molding, any known molding means for piezoelectric ceramics can be used. For example, it may be molded in sheet shape and then stacked. Also, an electrode paste to become an internal electrode may be applied on the surface of the sheet, which is then stacked. Alternatively, it may be molded in any desired bulk shape.

(4) Bake Step

The resultant molding is baked. Baking can be performed in the air.

Preferably, the bake temperature is not less than 1000° C. and not more than 1250° C. If it is less than 1000° C., the source material will not be sufficiently sintered, so that conduction is likely to occur upon polarization; therefore, the resultant ceramic may not have appropriate characteristics. If the bake temperature exceeds 1250° C., some of the elements composing the ceramic may precipitate, so that a ceramic exhibiting high piezoelectric characteristics may not be obtained. The preferable bake temperature is not less than 1050° C. and not more than 1200° C.

The bake time is not less than 0.5 hours and not more than 24 hours. If the bake time is shorter than 0.5 hours, the molding may not be completely sintered. If the bake time is longer than 24 hours, some of the elements composing the ceramic may vaporize. Preferably, it is not less than 1 hours and not more than 10 hours.

(5) Polarizing Treatment Step

Electrodes are formed on the ceramic obtained through the above steps, and the ceramic is subjected to a polarizing treatment. Through the polarizing treatment, a uniform direction of spontaneous polarization is attained in the ceramic, whereby piezoelectric characteristics exhibit themselves. For the polarizing treatment, known polarizing treatments which are generally employed in the production of piezoelectric ceramics can be used. For example, the baked substance having electrodes formed therein is retained at a temperature which is not less than room temperature and not more than 200° C. in a silicone bath or the like, and a voltage of not less than about 0.5 kV/mm and not more than about 6 kV/mm is applied thereto. As a result, a piezoelectric ceramic having piezoelectric characteristics can be obtained.

The piezoelectric ceramic of the present embodiment can be suitably used for a piezoelectric element. Specifically, such a piezoelectric element includes a piezoelectric layer composed of the above-described piezoelectric ceramic and a pair of electrodes between which the piezoelectric layer is interposed. The piezoelectric element may include a single structure as described above, or have a multilayer structure in which a plurality of piezoelectric layers and a plurality of electrodes are alternately stacked.

Hereinafter, Examples of the piezoelectric ceramic according to the present embodiment will be described in detail.

### EXAMPLES 1-1 TO 1-6, COMPARATIVE EXAMPLES 1-1 TO 1-5

In the general formula: sA1B1O₃-t(Bi.A2)TiO₃-(1-s-t)BaMO₃, piezoelectric ceramics of Examples 1-1 to 1-6 and Comparative Examples 1-1 to 1-5 having compositions as shown in Table 1 were produced.

As an alkali metal-containing niobium oxide-based composition, K₂CO₃, Na₂CO₃, Li₂CO₃, and Nb₂O₅ (alkaline niobate material) were weighed so that K, Na, Li, and Nb had mole fractions as indicated by (K_{0.45}Na_{0.5}Li_{0.05})NbO₃.

Moreover, BaCO₃, ZrO2, Bi2O₃, Na₂CO₃, and TiO2 were weighed and added to the above alkaline niobate material so that the compositions shown in Table 1 were attained.

These source materials were mixed in a ball mill. By using ethanol as a solvent and zirconia balls as the medium, mixing was conducted for 24 hours at revolutions of 94 rpm. Next, the medium and the source material were taken out of the ball mill vessel, and the medium and the source material were separated through a sieve. Thereafter, drying was conducted in the air at 130° C.

The mixed source material powder which had been dried was press-formed into disk shape, and calcined by being retained in the air at a temperature of 1050° C. for 3 hours. Then, the calcined molding which had solidified were crushed into powder by using a grinding and mixing machine or the like, and thereafter 24 hours of mixing was performed at revolutions of 94 rpm, by using ethanol as a solvent and zirconia balls as the medium. After mixing, the medium and the source material were separated through a sieve, and drying was conducted in the air at 130° C., thereby obtaining calcined powder.

The resultant calcined powder was press-formed into disk shape with a diameter of 13 mm and a thickness of 1.0 mm.

The resultant molding was baked in a baking furnace at 1200° C., and cooled down to room temperature.

Ag electrodes were formed on the resultant baked substance, and thereafter a voltage of 4000 V/mm was applied thereto in silicone oil at 150° C., thereby conducting a polarizing treatment.

A piezoelectric constant d33₍₂₅₎ at room temperature, a piezoelectric constant d33₍₁₀₀₎ at 100° C., a piezoelectric constant d33₍₂₀₀₎ at 200° C., and a Curie temperature Tc were measured. The method of measurement was as follows.

The piezoelectric constant d33 was measured by using a ZJ-6B type d33 meter (manufactured by The Chinese Academy of Sciences). The Curie temperature was measured with an impedance analyzer. Specifically, the temperature dependence of relative dielectric constant was measured, and a temperature at which the relative dielectric constant read largest was defined as the Curie temperature. In a small tube furnace (quartz tube), a ceramic having a thermocouple and terminals attached thereon was inserted, and its temperature was measured with a YHP4194A impedance analyzer (manufactured by Hewlett-Packard Company).

Table 1 shows the mole fractions, the piezoelectric constant d33₍₂₅₎ at room temperature, the piezoelectric constant d33₍₁₀₀₎ at 100° C., the piezoelectric constant d33₍₂₀₀₎ at 200° C., the rate Δd33(=(d33₍₂₅₎−d33₍₂₀₀₎)/d33₍₂₅₎) of a difference between the piezoelectric constant d33₍₂₅₎ at room temperature and the piezoelectric constant d33₍₂₀₀₎ at 200° C. to the piezoelectric constant d33₍₂₅₎ at room temperature (25° C.), and the Curie temperature Tc of each piezoelectric ceramic.

FIG. 1 is a diagrammatic illustration of the compositions shown in Table 1, where white circles are Examples, and black circles are Comparative Examples. The number in each circle corresponds to the right-hand digit of

TABLE 1

| | | d33₍₂₅₎ | d33₍₁₀₀₎ | d33₍₂₀₀₎ | | Tc |
|---|---|---|---|---|---|---|
| Sample | Composition | (pC/N) | (pC/N) | (pc/N) | Δd33 | (° C.) |
| Example1-1 | 0.915 (K_{0.45}Na_{0.5}Li_{0.05}) NbO₃-0.01 (Bi_{0.5}Na_{0.5}) | 298 | 294 | 288 | 0.034 | 271 |
| | TiO₃-0.075BaZrO₃ | | | | | |
| Example1-2 | 0.910 (K_{0.45}Na_{0.5}Li_{0.05}) NbO₃-0.01 (Bi_{0.5}Na_{0.5}) | 281 | 275 | 268 | 0.046 | 263 |
| | TiO₃-0.080BaZrO₃ | | | | | |
| Example1-3 | 0.905 (K_{0.45}Na_{0.5}Li_{0.05}) NbO₃-0.01 (Bi_{0.5}Na_{0.5}) | 254 | 246 | 236 | 0.071 | 254 |
| | TiO₃-0.085BaZrO₃ | | | | | |
| Example1-4 | 0.905 (K_{0.45}Na_{0.5}Li_{0.05}) NbO₃-0.02 (Bi_{0.5}Na_{0.5}) | 270 | 261 | 241 | 0.107 | 250 |
| | TiO₃-0.075BaZrO₃ | | | | | |
| Example1-5 | 0.910 (K_{0.45}Na_{0.5}Li_{0.05}) NbO₃-0.02 (Bi_{0.5}Na_{0.5}) | 320 | 300 | 280 | 0.125 | 254 |
| | TiO₃-0.070BaZrO₃ | | | | | |
| Example1-6 | 0.918 (K_{0.45}Na_{0.5}Li_{0.05}) NbO₃-0.01 (Bi_{0.5}Na_{0.5}) | 315 | 310 | 297 | 0.057 | 280 |
| | TiO₃-0.072BaZrO₃ | | | | | |
| Comparative | 0.915 (K_{0.45}Na_{0.5}Li_{0.05}) NbO₃-0.085BaZrO₃ | 195 | 188 | 166 | 0.149 | 264 |
| Example1-1 | | | | | | |
| Comparative | 0.920 (K_{0.45}Na_{0.5}Li_{0.05}) NbO₃-0.01 (Bi_{0.5}Na_{0.5}) | 280 | 271 | 258 | 0.079 | 286 |
| Example1-2 | TiO₃-0.070BaZrO₃ | | | | | |
| Comparative | 0.900 (K_{0.45}Na_{0.5}Li_{0.05}) NbO₃-0.01 (Bi_{0.5}Na_{0.5}) | 186 | 179 | 168 | 0.097 | 250 |
| Example1-3 | TiO₃-0.090BaZrO₃ | | | | | |
| Comparative | 0.920 (K_{0.45}Na_{0.5}Li_{0.05}) NbO₃-0.02 (Bi_{0.5}Na_{0.5}) | 232 | 223 | 189 | 0.185 | 273 |
| Example1-4 | TiO₃-0.060BaZrO₃ | | | | | |
| Comparative | 0.900 (K_{0.45}Na_{0.5}Li_{0.05}) NbO₃-0.03 (Bi_{0.5}Na_{0.5}) | 239 | 225 | 192 | 0.197 | 246 |
| Example1-5 | TiO₃-0.070BaZrO₃ | | | | | |

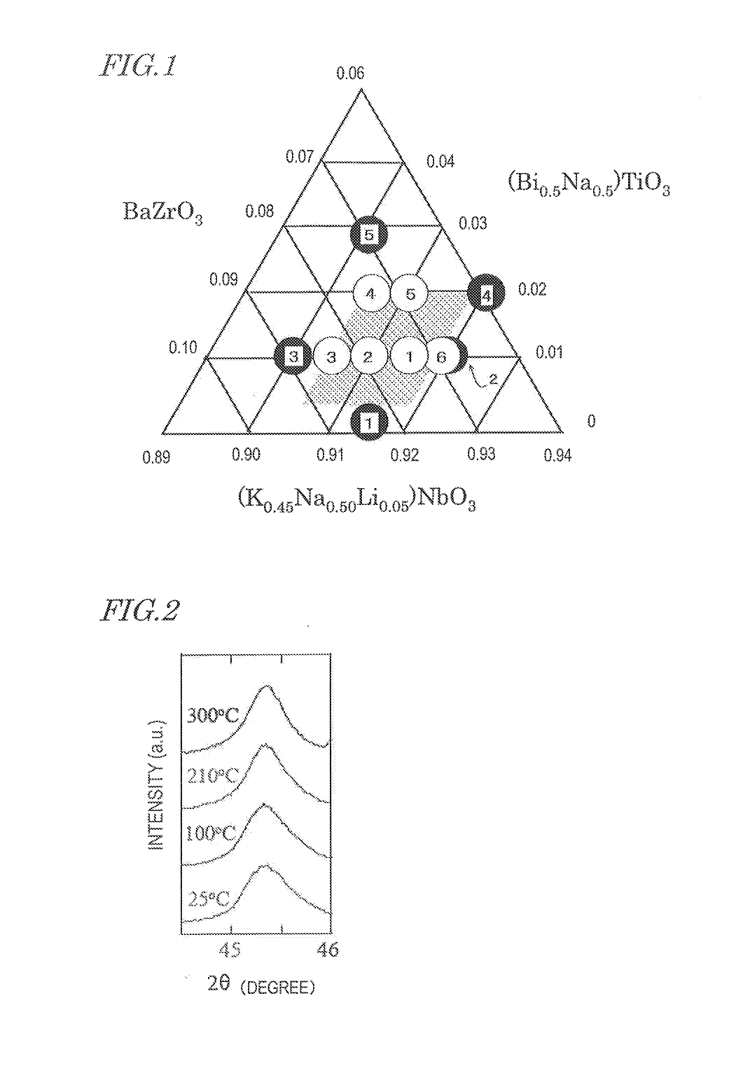

FIG. 2 shows a result of X-ray analysis (25° C., 100° C., 210° C., 300° C.) of the piezoelectric ceramic of Example 1-3. At all of these temperatures, peaks which are observed between 44.5° and 46° pertain to the (200)_{pc} crystal orientation in a pseudo-cubic representation of the perovskite structure, thus indicative of a rhombohedral crystal structure. As seen from FIG. 2, the peaks of 25° C. to 300° C. all have similar half-widths, and the peaks are hardly varied in position. In other words, it can be seen that the piezoelectric ceramic of the composition of Example 1-3 does not exhibit any phase change between 25° C. and 300° C., and is rhombohedral at all such temperatures. This indicates that the phase boundary in at least this temperature range exists on the side with more A1B1O₃ ((K_{0.45}Na_{0.5}Li_{0.05})NbO₃) than indicated by mole fractions of Example 1-3.

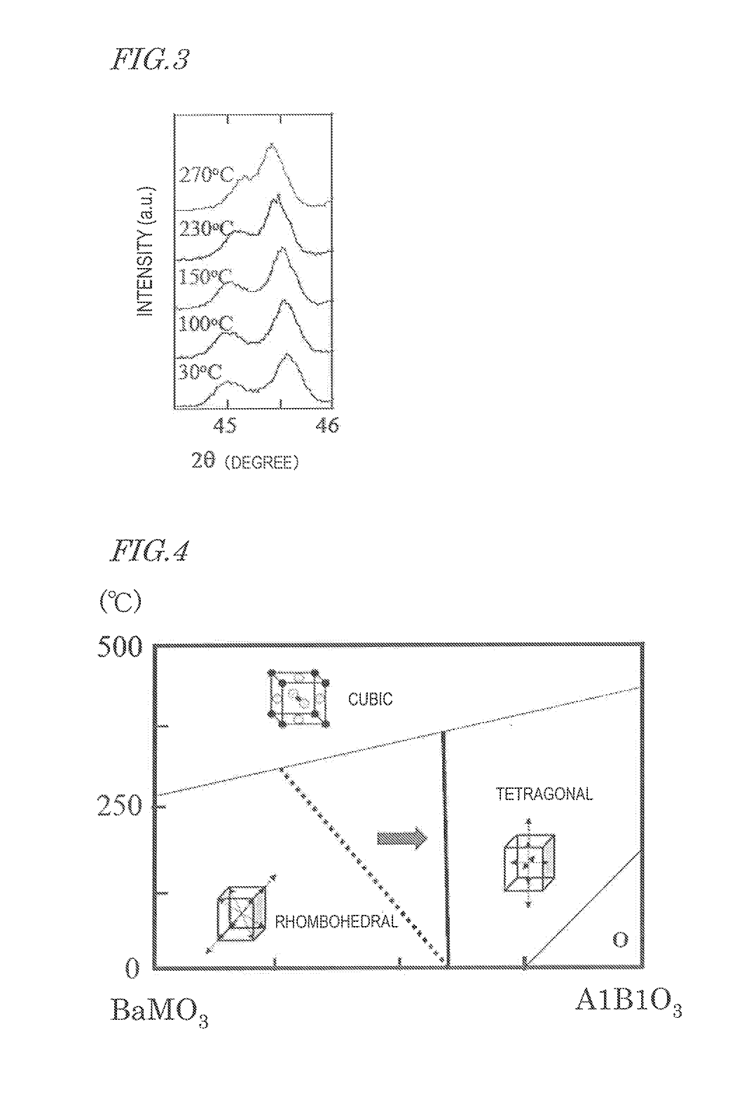

FIG. 3 shows a result of X-ray analysis (30° C., 100° C., 150° C., 230° C., 270° C.) of the piezoelectric ceramic of Example 1-6. At all of these temperatures, peaks which are observed between 44.5° and 46° pertain to the (200) and (002) crystal orientations in the perovskite structure, thus indicative of a tetragonal crystal structure. In other words, it can be seen that the piezoelectric ceramic of the composition of Example 1-6 does not exhibit any phase change between 30° C. and 270° C., and is tetragonal at all such temperatures. This indicates that the phase boundary in at least this temperature range exists on the side with more A1B1O₃ ((K_{0.45}Na_{0.5}Li_{0.05})NbO₃) than indicated by the mole fractions of Example 1-6.

From the above results, it can be seen that the phase boundary between rhombohedral and tetragonal exists in at least the very narrow composition range between Example 1-3 and Example 1-6 and across the entire temperature range from room temperature to 300° C.

Within the range of the above general formula, the piezoelectric ceramic according to the present disclosure has its phase boundary lying parallel to the temperature axis in the phase diagram of FIG. 4, and therefore is suitably used in environments of use across a broad temperature range.

The piezoelectric ceramics of Examples 1-1 to 1-6 were evaluated with respect to temperature stability. The piezoelectric constant d33₍₂₅₎ at room temperature and the piezoelectric constant d33₍₂₀₀₎ at 200° C. were measured, and a rate Δd33 of their difference was calculated to be all 0.13 or less. In particular, the piezoelectric ceramics of Examples 1-1 to 1-3, whose s and t are in the range of 0.910≦s<0.918, t=0.01, showed even more excellent values, i.e., their rates of difference d33 being 0.10 or less. Upon conducting an additional experiment in order to specifically study the preferable range of t, it was confirmed that the rate of difference d33 will be 0.10 or less when 0.06≦t≦0.015 is satisfied.

FIG. 5 shows a result of X-ray analysis (30° C., 100° C., 200° C., 270° C., 300° C.) of the piezoelectric ceramic of Comparative Example 1-1. It can be seen that the peaks which are observed between 44.5° and 46° at 30° C. to 200° C. gradually changes from the (200)_{pc} crystal orientation in the pseudo-cubic representation of the perovskite structure to the (200) and (002) crystal orientations. In other words, it can be seen that the crystal structure changes from rhombohedral to tetragonal as temperature increases. This is presumably because, as shown by the broken line in FIG. 4, the oblique phase boundary of this piezoelectric ceramic causes the crystal structure to change with temperature.

Therefore, as temperature changes, the piezoelectric ceramic of Comparative Example 1-1 experiences large changes in crystal structure, e.g., shifting from a crystal structure near the phase boundary region to a completely rhombohedral or tetragonal crystal structure, or undergoing a phase transition from rhombohedral to tetragonal, etc., thus having low temperature stability.

Specifically, Δd33(=(d33₍₂₅₎−d33₍₂₀₀₎/d33₍₂₅₎) of the piezoelectric ceramic of Comparative Example 1-1 was 0.152, which is greater than 0.13.

Moreover, Δd33 values of the piezoelectric ceramics of Comparative Examples 1-2 to 1-5 were all above 0.13.

### EXAMPLE 2

An experiment was conducted for the piezoelectric ceramic of Example 1-1 while varying its Li amount. Specifically, K, Na, Li, and Nb in the A1B1O₃ composition were prescribed so as to give (K_{0.48}Na_{0.5}Li_{0.02})NbO₃, (K_{0.46}Na_{0.5}Li_{0.04})NbO₃, and (K_{0.42}Na_{0.5}Li_{0.08})NbO₃. Except for this difference, the piezoelectric ceramics were produced by a similar production method and similar conditions to those for Example 1-1.

Table 2 shows the composition, the piezoelectric constant d33₍₂₅₎ at room temperature, the piezoelectric constant d33₍₁₀₀₎ at 100° C., the piezoelectric constant d33₍₂₀₀₎ at 200° C., the rate Δd33(=(d33₍₂₅₎−d33₍₂₀₀₎)/d33₍₂₅₎) of a difference between the piezoelectric constant d33₍₂₅₎ at room temperature and the piezoelectric constant d33₍₂₀₀₎ at 200° C. to the piezoelectric constant d33₍₂₅₎ at room temperature (25° C.), and the Curie temperature Tc of each piezoelectric ceramic.

TABLE 2

| | | d33₍₂₅₎ | d33₍₁₀₀₎ | d33₍₂₀₀₎ | | Tc |
|---|---|---|---|---|---|---|
| Sample | Composition | (pC/N) | (pC/N) | (pC/N) | Δd33 | (° C.) |
| Example2-1 | 0.915 (K_{0.48}Na_{0.5}Li_{0.02}) NbO₃-0.01 (Bi_{0.5}Na_{0.5}) | 299 | 293 | 287 | 0.040 | 258 |
| | TiO₃-0.075BaZrO₃ | | | | | |
| Example2-2 | 0.915 (K_{0.46}Na_{0.5}Li_{0.04}) NbO₃-0.01 (Bi_{0.5}Na_{0.5}) | 287 | 282 | 277 | 0.035 | 269 |
| | TiO₃-0.075BaZrO₃ | | | | | |
| Example2-3 | 0.915 (K_{0.42}Na_{0.5}Li_{0.08}) NbO₃-0.01 (Bi_{0.5}Na_{0.5}) | 279 | 275 | 270 | 0.032 | 280 |
| | TiO₃-0.075BaZrO₃ | | | | | |

It can be seen from the results of Table 2 that the Curie temperature is improved as the Li amount increases. In the general formula according to the present disclosure, the piezoelectric ceramic of Example 2-2 in which K, Na, Li, and Nb in the A1B1O₃ composition are prescribed to be (K_{0.46}Na_{0.5}Li_{0.04})NbO₃ (i.e., 3.66 at % Li is contained relative to the total amount of A1, Bi, A2, and Ba), and the piezoelectric ceramic of Example 2-3 prescribed to be (K_{0.46}Na_{0.5}Li_{0.08})NbO₃ (i.e., 7.32 at % Li is contained relative to the total amount of A1, Bi, A2, and Ba) have Curie temperatures Tc of 200° C. or more.

However, Table 2 indicates a tendency that the piezoelectric constant d33 decreases with excessive Li. Therefore, it is preferable that Li is contained in an amount of 7.32 at % or less relative to the total amount of A1, Bi, A2, and Ba.

A piezoelectric ceramic, a composition for piezoelectric ceramics, and a piezoelectric element according to the present disclosure are suitably used in fields such as electronics, mechatronics, and automobiles.

While the present disclosure has been described with respect to exemplary embodiments thereof, it will be apparent to those skilled in the art that the disclosed disclosure may be modified in numerous ways and may assume many embodiments other than those specifically described above. Accordingly, it is intended by the appended claims to cover all modifications of the disclosure that fall within the true spirit and scope of the disclosure.

This application is based on Japanese Patent Applications No. 2013-204281 filed on Sep. 30, 2013, the entire contents of which are hereby incorporated by reference.

What is claimed is:

1. A piezoelectric ceramic comprising as a main component an oxide which is represented by the general formula: sA1B1O₃-t(Bi.A2)TiO₃-(1-s-t)BaMO₃ (where A1 is at least one element selected from among alkali metals; B1 is at least one element selected from among transition metal elements and contains Nb; A2 is at least one element selected from among alkali metals; and M is at least one element selected from the 4A group and contains Zr), wherein,
s and t in the general formula satisfy 0.905≦s≦0.918, 0.005≦t≦0.02; and
a piezoelectric constant d33₍₂₅₎ at 25° C. and a piezoelectric constant d33₍₂₀₀₎ at 200° C. satisfy the following relationship:
$$\frac{d {33}_{( 25 )} - d {33}_{( 200 )}}{d {33}_{( 25 )}} \leq 0.13 .$$

2. The piezoelectric ceramic of claim 1, wherein the piezoelectric constant d33₍₂₅₎ is 200 pC/N or more.

3. The piezoelectric ceramic of claim 1, wherein, s and t in the general formula satisfy
0.910≦s<0.918
0.006≦t≦0.015; and
the piezoelectric constant d33₍₂₅₎ and the piezoelectric constant d33₍₂₀₀₎ satisfy the following relationship:
$$\frac{d {33}_{( 25 )} - d {33}_{( 200 )}}{d {33}_{( 25 )}} \leq 0.10 .$$

4. A piezoelectric element comprising a piezoelectric layer composed of the piezoelectric ceramic of claim 1, and a pair of electrodes between which the piezoelectric layer is interposed.

5. A composition for a piezoelectric ceramic, comprising as a main component a composition represented by the general formula: sA1B1O₃-t(Bi.A2)TiO₃-(1-s-t)BaMO₃ (where A1 is at least one element selected from among alkali metals; B1 is at least one element selected from among transition metal elements and contains Nb; A2 is at least one element selected from among alkali metals; M is at least one element selected from the 4A group and contains Zr; and 0.905≦s≦0.918, 0.005≦t≦0.02).

6. The composition for a piezoelectric ceramic of claim 5, wherein s and t in the general formula satisfy:
0.910≦s<0.918
0.006≦t≦0.015.

7. The composition for a piezoelectric ceramic of claim 6, wherein the general formula is s(KₓNa_{y}Li_{z})NbO₃-t(Bi_{0.5}Na_{0.5})TiO₃-(1-s-t)BaZrO₃(x+y+z=1).
